(19) United States
(12) Patent Application Publication
(10) Pub. No.: US 2004/0121566 A1
(43) Pub. Date: Jun. 24, 2004

(54) Method to produce low leakage high K materials in thin film form

(75) Inventors: Robert Benjamin Laibowitz, Cortlandt Manor, NY (US); Jingyu Lian, Tokyo (JP)

Correspondence Address: LERNER, DAVID, LITTENBERG,, KRUMHOLZ & MENTLIK, 600 SOUTH AVENUE WEST, WESTFIELD, NJ, 07090, US

(73) Assignee: Infineon Technologies North America Corp, San Jose, CA

(21) Appl. No.: 10/327,728

(22) Filed: Dec. 23, 2002

(51) Int. Cl. C30B 1/00

(52) U.S. Cl. 438/482

(57) ABSTRACT

High K dielectric materials having very low leakage current are formed by depositing a thin amorphous layer of a high K dielectric and a crystalline layer of a high K dielectric over the amorphous layer. Semiconductor devices including composite high K dielectric materials, and methods of fabricating such devices, are also disclosed.

### BACKGROUND OF THE INVENTION

The present invention relates to semiconductor fabrication. More particularly, the present invention relates to thin film high dielectric constant materials for use in semiconductor devices.

Semiconductor devices are employed in various systems for a wide range of applications. Two ubiquitous semiconductor devices are transistors and capacitors, which are often used as part of larger devices or systems. As an example, transistors may form part of a logic device. As another example, a transistor and a capacitor may be used in the creation of memory cells such as dynamic random access memory (“DRAM”).

A simple DRAM cell may include one transistor and one capacitor formed on or within a semiconductor substrate. The capacitor stores a charge to represent a data value. The transistor allows the data value to be refreshed, read from or written to the capacitor. FIG. 1A illustrates a convention DRAM memory cell 100 including a capacitor 110 and a transistor 120. The capacitor 110 includes a first electrode 112 and a second electrode 114, which are typically separated by a dielectric (not shown). The transistor 120 includes a source (or drain) 122 connected to the second electrode 114. The transistor 120 also includes a drain (or source) 124 connected to a bit line 132, as well as a gate 126 connected to a word line 130. The data value may be refreshed, read from or written to the capacitor 110 by applying appropriate voltage to the transistor 120 through the word line 130 and/or the bit line 132.

FIG. 1B illustrates an exemplary capacitor in more detail. Specifically, the figure shows a dielectric material 116 between the first electrode 112 and the second electrode 114. FIG. 1C illustrates an exemplary transistor in more detail. The transistor 120 is typically formed on a semiconductor substrate 102. A gate dielectric 128 is formed between the gate 126 and the substrate 102. Conduction through the substrate 102 below the gate dielectric 128 and between the source (drain) 122 and the drain (source) 124 may be controlled by applying appropriate voltages to the gate 126, the source (drain) 122 and the drain (source) 124.

Semiconductor manufacturers continually seek new ways to improve performance, decrease cost and increase capacity of semiconductor devices. Capacity and cost improvements may be achieved by shrinking device size. In the case of DRAM, more memory cells can fit onto a semiconductor chip by reducing the size of the capacitor and/or the transistor, thus resulting in greater memory capacity for the chip. Cost reduction is achieved through economies of scale. Unfortunately, performance can suffer when device components are shrunk. Therefore, it is a challenge to balance performance with other manufacturing constraints.

In order to achieve satisfactory performance, manufacturers often change materials and vary process conditions. For example, one of the most important parameters for a memory cell is capacitance. Capacitance is the ratio of the charge on either electrode of the capacitor to the magnitude of the potential difference between the electrodes. The capacitance may affect memory cell parameters including data retention time, sensing speed and sensing signal voltage. Generally, the higher the capacitance, the more robust the memory cell. Typically, a DRAM memory cell requires a capacitance on the order of 25-30 fF.

The area of the capacitor, the dielectric constant of the dielectric material, and the thickness of the dielectric material effectively determine the level of capacitance. Increasing the area, increasing the dielectric constant and/or decreasing the thickness of the dielectric material increases the capacitance. Because capacitor area is often limited in small-scale, high-density DRAM such as Gigabit DRAM, improved capacitance is sought using dielectric materials having higher dielectric constants at reduced thickness. Similarly, the gate dielectric 128 can substantially affect the performance of the transistor 120. As with the capacitors, high performance small-scale transistors require thin gate dielectric materials having high dielectric constants.

Recent efforts for improving capacitor and transistor functionality have focused on improved dielectric materials having high dielectric constants. Dielectric materials having high dielectric constants are known as “high K” materials. A widely used dielectric material is silicon dioxide (SiO₂), which has a dielectric constant of approximately 3.9. SiO₂ has been used as the dielectric material for conventional capacitors and transistors. As used herein, high K materials have a dielectric constant greater than SiO₂.

There are a variety of high K materials which have been utilized in an attempt to replace SiO₂. Table 1 identifies several such materials, with SiO₂ as a reference.

TABLE 1
High K dielectric materials

| | Dielectric |
|---|---|
| Dielectric Material | Constant |
| Silicon dioxide (SiO₂) | 3.9 |
| Silicon nitride (Si₃N₅) | 7-8 |
| Aluminum Oxide (Al₂O₃) | 8-10 |
| Zirconium oxide (ZrO₂) | ˜14-28 |
| Titanium oxide (TiO₂) | ˜30-80 |
| Tantalum pentoxide (Ta₂O₅) | ˜25-50 |
| Barium-strontium-titanate (BST/BSTO) | ˜100-800 |
| Strontium-titanate-oxide (STO) | ˜230+ |
| Lead-zirconium-titanate (PZT) | ˜400-1500 |

While the materials listed in table 1 are not an exhaustive list of high K dielectrics, they represent a broad spectrum of dielectric values. The dielectric values for some of the materials, e.g., BST (also known as BSTO), STO and PZT, can vary widely depending upon the processing, the specific composition, dopants (if any) and other parameters such as crystallinity and dielectric thickness. For example, the dielectric constant can change depending upon whether the material is amorphous or crystalline. An amorphous material lacks an orderly crystalline structure. In contrast, a crystalline material has an atomic structure arranged in a specific pattern. For high K materials such as BST, crystalline forms of the material have higher dielectric constants than amorphous forms of the material. Different high K dielectrics may be formed in different ways. Typically, Ta₂O₅, TiO₂ and ZrO₂ are formed using metal oxide chemical vapor deposition (“MOCVD”). BST and STO are typically formed using a combination of MOCVD and molecular beam epitaxy (“MBE”). PZT is typically formed by either vapor deposited or solution deposition (e.g., “sol-gel” deposition).

A critical problem with thin high K dielectrics is leakage current. Generally speaking, leakage current is an unwanted parasitic current flowing through the semiconductor device. For example, leakage current occurs in capacitors through the dielectric. Defects, grain boundaries and interfacial states can enhance leakage because they allow more current to be injected. In a capacitor, the charge leaking off may be replaced by “refreshing” the device, which can create added expense, complexity or inefficient use of resources. Also, leakage current tends to increase substantially as dielectric thickness decreases. In order for devices to function properly, it is desirable to keep leakage current below 1×10⁻⁵ A/cm² at 1 volt. It is even more preferable to keep leakage current below 1×10 ⁻⁷ A/cm² at 1 volt. However, such a low leakage current is very difficult to achieve in relatively low thickness dielectrics.

One method of forming high K dielectric material with low leakage current employs an amorphous film of a high K material. The amorphous film, which is between 1 to 2000 nm thick, is deposited at temperatures below 450° C. The amorphous film is then annealed at temperatures between 150° C. to 450° C. As an example, a conventionally formed amorphous BST dielectric having a thickness of 77 nm may have a leakage current of 1×10⁻⁷ A/cm² at 1 volt. However the same amorphous BST having a thickness of 45 nm may have a leakage current of 10×⁻⁵ A/cm² at 1 volt. As discussed above and as shown in this example, decreasing the thickness can drastically increase the leakage current. The 45 nm film, while providing an acceptable leakage current value, may be too thick for advanced small-scale devices.

An alternative method of forming high K dielectric material includes first depositing a thin non-contiguous “seed” layer of high K dielectric, e.g., BST, using a gas followed by depositing a second high K dielectric layer on top of the seed layer. The seed layer is “nucleated,” meaning that it is not uniformly deposited but instead forms a series of dielectric particles (nuclei) distributed across the base material. The second layer of, e.g., BST, is grown at temperatures between 550° C. and 700° C. using the seed nuclei as a base. While such a process can result in dielectric having a capacitance of 50 fF/μm² to 500 fF/μm², it does not address the leakage current problem.

### SUMMARY OF THE INVENTION

A need exists for improved high K dielectric materials. These improved high K dielectrics need to be formed in thin layers yet achieve a very low leakage current. Furthermore, such materials should provide a sufficient capacitance for small-scale memory cells.

In accordance with one embodiment of the present invention, a method of fabricating a high K dielectric material is provided. The method comprises first providing a base material which has an upper surface. An amorphous layer of a first high K dielectric is formed on the base material such that the amorphous layer covers the upper surface. A crystalline layer of a second high K dielectric is then formed over the amorphous layer. The first and second high K dielectrics are preferably annealed at a selected temperature. The amorphous layer is preferably between 1 and 12 nm thick. The crystalline layer is preferably less than 45 nm thick. The amorphous layer is preferably formed by a physical vapor deposition such as sputtering, or by chemical vapor deposition. The crystalline layer is preferably formed by chemical vapor deposition at a temperature between 400° C. to 650° C.

In accordance with another embodiment of the present invention, a method of fabricating a portion of a semiconductor device is disclosed, wherein a base material having an upper surface is provided, an amorphous layer of a first high K dielectric is vapor deposited to cover the upper surface, and a crystalline layer of a second high K dielectric is vapor deposited over the amorphous layer. The amorphous layer is less than about 12 nm thick and the crystalline layer is less than about 45 nm thick. The amorphous layer and the crystalline layer are preferably annealed together to form a composite dielectric material having leakage current less than about 1×10⁻⁵ A/cm². The capacitance per unit area of the composite dielectric material is preferably at least 60 fF/μm².

In accordance with another embodiment of the present invention, a high K dielectric material for use in semiconductor devices is provided. The material comprises a continuous amorphous layer of a first high K dielectric and a crystalline layer of a second high K dielectric vapor deposited over the continuous amorphous layer. The continuous amorphous layer has a thickness less than 12 nm and the crystalline layer is less than 45 nm. Preferably, at least one of the first and second high K dielectrics is selected from the group consisting of STO, BTO, BST, PZT and SBT.

In accordance with yet another embodiment, a semiconductor device is provided wherein the device comprises first and second electrodes separated by a high K dielectric material. The first and second electrodes are formed on a semiconductor substrate. The high K dielectric material is formed from a continuous amorphous layer of a first high K dielectric and a crystalline layer of a second high K dielectric. Preferably, the first high K dielectric has a thickness less than 12 nm and the second high K dielectric has a thickness less than 45 nm.

In accordance with another embodiment of the present invention, a transistor is provided wherein the device comprises a source, a drain and a gate region. The source and the drain are disposed on a semiconductor substrate. The gate region is used to electrically connect the source and the drain. The gate region includes a gate material and a gate dielectric of a high K dielectric material. The high K dielectric is formed from a continuous amorphous layer of a first high K dielectric and a crystalline layer of a second high K dielectric. Preferably, the first high K dielectric has a thickness less than 12 nm and the second high K dielectric has a thickness less than 45 nm.

In accordance with yet another embodiment of the present invention, a method of fabricating a semiconductor device is provided. The method comprises forming a first electrode having a surface, depositing an amorphous layer of a first high K dielectric to cover the surface, depositing a crystalline layer of a second high K dielectric over the amorphous layer, and annealing the amorphous layer and the crystalline layer together to form a composite dielectric material. Preferably, the method includes forming a second electrode over the composite dielectric material. The amorphous layer is preferably less than about 12 nm and the crystalline layer is preferably less than about 45 nm.

In accordance with another embodiment of the present invention, a method of fabricating a transistor is provided. The method comprises forming a source on a semiconductor substrate, forming a drain on the semiconductor substrate, depositing an amorphous layer of a first high K dielectric over a surface region of the semiconductor substrate, depositing a crystalline layer of a second high K dielectric over the amorphous layer, annealing the amorphous layer and the crystalline layer together to form a composite dielectric material, and forming a gate material over the composite dielectric material. The amorphous film is preferably less than about 12 nm and the crystalline layer is preferably less than about 45 nm.

### BRIEF DESCRIPTION OF THE DRAWINGS

FIG. 1A depicts a conventional DRAM memory cell.

FIG. 1B illustrates an exemplary capacitor.

FIG. 1C illustrates an exemplary transistor.

FIG. 2 illustrates an initial step in a process of fabricating a dielectric material in accordance with aspects of the present invention.

FIG. 3 illustrates a subsequent step in a process of fabricating a dielectric material in accordance with aspects of the present invention.

FIG. 4 illustrates a further step in a process of fabricating a dielectric material in accordance with aspects of the present invention.

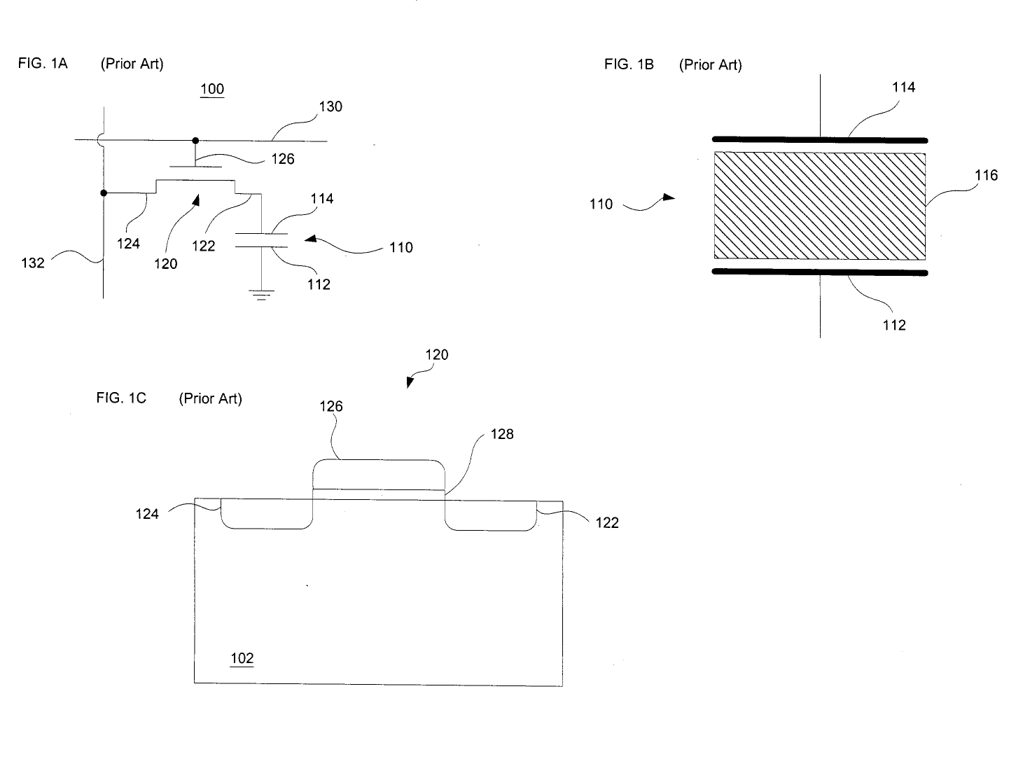

### DETAILED DESCRIPTION

Semiconductor devices of the present invention and methods of fabricating such devices provide thin high K dielectric materials having reduced leakage current. These dielectric materials are suitable for use in advanced capacitor and transistor structures, as well as other devices. The foregoing aspects, features and advantages of the present invention will be further appreciated when considered with reference to the following description of preferred embodiments and accompanying drawings, wherein like reference numerals represent like elements.

In accordance with an embodiment of the present invention, a method is provided to form a thin film high K dielectric material having low leakage current. As used with regard to the present invention, the term “thin” means below about 45 nm. The thin high K dielectric material is formed using two layers of dielectric material. The term “layer” includes thin films of varying thickness.

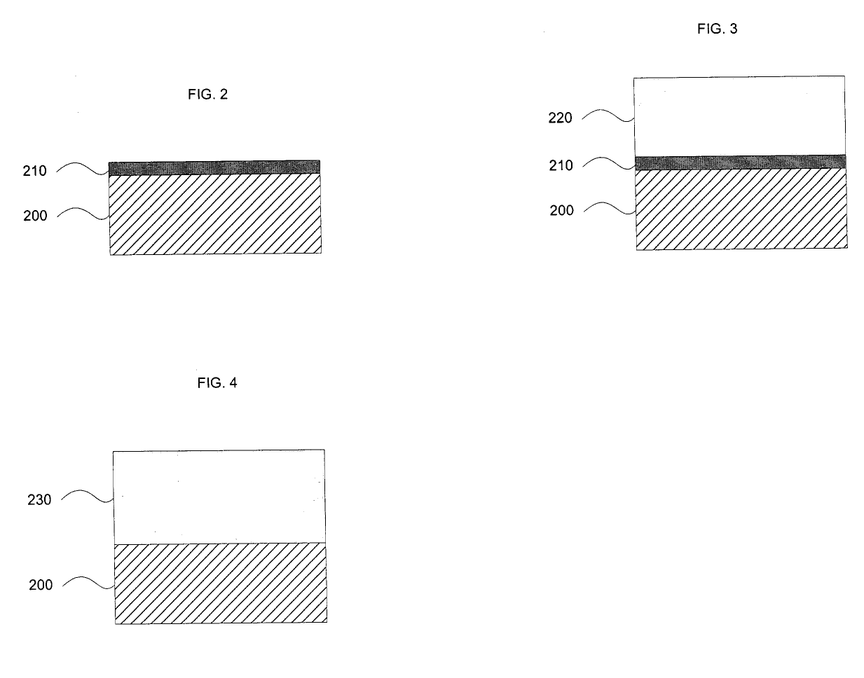

FIG. 2 illustrates a cross-sectional view of one stage in a process of fabricating the thin high K dielectric material. The thin dielectric is formed over a base 200, e.g., an electrode of a capacitor. The base 200 may be formed on a semiconductor substrate. “Forming” the base 200 includes, e.g., depositing, placing or otherwise providing the base 200 on the substrate. As used herein, the term “on” means on or within the substrate, whether or not in direct contact with the substrate. The base 200 is preferably platinum (Pt), although other suitable materials may be used. The process includes forming a layer of a thin amorphous film 210 of a high K dielectric material over the base 200. Desirably, the amorphous film 210 is between 1 and 12 nm. The amorphous film 210 is preferably less than about 1.5 nm, i.e., 15 Å thick. The thickness may vary slightly depending upon process conditions. The amorphous film 210 is thick enough to cover the base 200 and avoid pinholes, voids or other open areas. The amorphous film 210 preferably continuously covers the base 200. Stated another way, the amorphous film 210 is preferably contiguous over the base 200.

The amorphous film 210 is formed at low temperature. As used herein, the phrase “low temperature” means less than the crystallization temperature of the dielectric material. One reason to use a low temperature is to avoid crystallization of the high K dielectric. Another reason is to keep the overall thermal budget of the fabrication process as low as possible. Yet another reason is to reduce oxidation of barriers and contacts. Preferably, the amorphous film 210 is deposited at ambient temperature, e.g., room temperature.

The material of the amorphous film 210 can be selected from many high K dielectrics. By way of example only, the material may be STO, BST, PZT, strontium bismuth tantalite (SBT), barium titanate oxide (BTO) or another metal oxide. The amorphous film 210 may be formed using a vapor deposition process such as physical vapor deposition (“PVD”) or chemical vapor deposition (“CVD”), and preferably comprises a single high K dielectric material.

PVD involves first converting a source material into a gaseous or vapor phase, transporting that gaseous or vapor material from the source material to a substrate, and then condensing the gaseous material onto the substrate. Preferably, sputtering is employed to deposit the amorphous film 210. Sputtering is a PVD process which bombards a solid source material with high energy ions of, e.g., argon. The bombardment causes some of the atoms to dislodge from the solid. The free atoms then redeposit onto a target surface, such as the surface of the base 200.

The PVD/sputtering process desirably occurs at room temperature. The pressure may be in the range of 1 to 100 mTorr, preferably about 10 mTorr. The thickness of the amorphous film 210 will depend upon the duration of the PVD/sputtering.

In CVD, a thin film is formed on the base 200 using a controlled chemical reaction. CVD, like PVD, is well known in the art. To form the amorphous film 210, the CVD process preferably takes place below 400° C. More preferably, the CVD process occurs at ambient or room temperature. The pressure of the CVD process may be approximately 1 Torr.

Whether to use PVD or CVD effectively depends upon the dielectric material to be used for the amorphous film 210. By way of example only, STO may be deposited using PVD/sputtering and BST may be deposited using CVD in accordance with the above-identified parameters.

As shown in FIG. 3, a thin crystalline layer 220 of a high K dielectric is formed over the amorphous film 210. The crystalline layer 220 uses the amorphous film 210 as a base on which to grow. Therefore, it is important that the amorphous film 210 provides good coverage, e.g., without pinholes or other gaps or voids.

The crystalline layer 220 should be less than 45 nm, and preferably less than 30 nm. As with the amorphous film 210, the material of the crystalline layer 220 can be selected from many high K dielectrics. By way of example only, the material may be STO, BST, PZT, SBT, BTO or another metal oxide. The crystalline layer 220 may comprise one or more high K dielectric materials, and may be the same or a different material than the amorphous film 210.

The crystalline layer 220 is preferably deposited using a vapor deposition process such as CVD. The temperature of the process is preferably in the range of 400° C. to 650° C. More preferably, the temperature is between 500° C. and 650° C. The pressure may be the same pressure as in the formation of the amorphous film 210. The dielectric material of the crystalline layer 220 may be chosen to be a ferroelectric or non-ferroelectric material.

The crystalline layer 220 and the amorphous film 210 are preferably annealed at an elevated temperature to produce a composite dielectric material 230, as shown in FIG. 4. Annealing preferably occurs for a short period of time, such as 15 minutes. The elevated temperature is preferably about 450° C. Annealing may occur in the presence of a gas such as oxygen (O₂). Annealing will preferably crystallize the amorphous film 210. The composite dielectric material 230 is a thin layer of high K dielectric having a leakage current at least as low as 1×10 ⁻⁵ A/cm² relative to 1 volt. The processing may continue by, for example, depositing a second electrode over the composite dielectric material 230.

Table 2 provides experimental results using the aforementioned process. In the experiments, the amorphous film 210 was formed over a platinum electrode. The data was measured after annealing at 450° C. in oxygen for 15 minutes.

TABLE 2
Experimental results

| | Crystalline | Capacitance | Leakage Current |
|---|---|---|---|
| Amorphous Film | Layer | per Area | (A/cm²) |
| PVD STO | CVD BST (30 nm) | 60 fF/μm² | 4 × 10⁻⁸ A/cm² |
| PVD STO | CVD BST (12 nm) | 65 fF/μm² | 1 × 10⁻⁵ A/cm² |
| CVD BST | CVD BST (30 nm) | 66 fF/μm² | 7 × 10⁻⁸ A/cm² |
| CVD BST | CVD BST (12 nm) | 66 fF/μm² | 2 × 10⁻⁷ A/cm² |

As shown by the experimental results, a crystalline layer 220 of BST was formed in each test using CVD. In two tests, the amorphous film 210 was STO formed by PVD, and in the other tests the amorphous film 210 was BST formed by CVD. The amorphous films 210 ranged between about 1 and 12 nm thick. The highest leakage current was 1×10⁻⁵ A/cm² using PVD-deposited STO and a BST 12 nm thick. The other examples showed even lower leakage currents between 2×10⁻⁷ A/cm² and 7×10⁻⁸ A/cm². Also, each dielectric provided a high capacitance per square micron, thereby being beneficial for small-scale capacitors. The overall dielectric constants of the newly formed materials were in the approximate range of 75 to 200. Such results are a substantial improvement over prior techniques using thicker dielectric materials.

One advantage of the present invention is that thin, high K dielectric materials may be formed having a leakage current below 1×10 ⁻⁵ A/cm². Another advantage of the present invention is the formation of thin dielectric materials having suitably high capacitance for use in small-scale capacitors. Yet another advantage of the present invention is that high K dielectric materials may be formed with a thickness less than 45 nm. A further advantage is the formation of dielectric materials at low temperatures, thereby preventing unwanted oxidation and reducing thermal expenditures.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of fabricating a high K dielectric material, comprising:
(a) providing a base material having an upper surface;
(b) forming an amorphous layer of a first high k dielectric on the upper surface of the base material such that the amorphous layer covers the base material; and
(c) forming a crystalline layer of a second high K dielectric over the amorphous layer.

2. The method according to claim 1, further comprising annealing the first and second high K dielectrics at a selected temperature.

3. The method of claim 2, wherein the selected temperature is 450° C., and the annealing is performed in the presence of oxygen.

4. The method of claim 1, wherein the amorphous layer between 1 and 12 nm thick.

5. The method of claim 1, wherein the amorphous layer is formed by physical vapor deposition.

6. The method of claim 5, wherein the physical vapor deposition is sputtering.

7. The method of claim 5, wherein the physical vapor deposition is performed at ambient temperature.

8. The method of claim 1, wherein the amorphous layer is formed by chemical vapor deposition.

9. The method of claim 8, wherein the chemical vapor deposition is performed at a temperature below 400° C.

10. The method of claim 1, wherein the first high K dielectric is selected from the group consisting of STO, BTO, BST, PZT and SBT.

11. The method of claim 1, wherein the second high K dielectric is selected from the group consisting of STO, BTO, BST, PZT and SBT.

12. The method of claim 1, wherein the crystalline layer is less than about 45 nm thick.

13. The method of claim 1, wherein the crystalline layer is formed by chemical vapor deposition.

14. The method of claim 13, wherein the chemical vapor deposition is performed at a temperature between 400° C.-650° C.

15. A method of fabricating a portion of a semiconductor device, the method comprising:
(a) providing a base material having an upper surface;
(b) vapor depositing an amorphous layer of a first high K dielectric to cover the upper surface of the base material, the amorphous layer being less than about 12 nm thick; and
(c) vapor depositing a crystalline layer of a second high K dielectric over the amorphous layer, the crystalline layer being less than 45 nm thick.

16. The method of claim 15, further comprising annealing the amorphous layer and the crystalline layer together to form a composite dielectric material having leakage current less than about 1×10⁻⁵ A/cm².

17. The method of claim 16, wherein capacitance per unit area of the composite dielectric material is at least 60 fF/μm².

18. The method of claim 15, wherein the second high K dielectric is BST formed by chemical vapor deposition at a temperature between 400° C. and 650° C.

19. The method of claim 18, wherein the amorphous layer of the first high K dielectric is STO, and the STO is deposited using physical vapor deposition at ambient temperature.

20. The method of claim 19, wherein the physical vapor deposition is sputtering.

21. The method of claim 18, wherein the amorphous layer is deposited using chemical vapor deposition at a temperature below 400° C. and the first high K dielectric is BST.

22. A method of fabricating a semiconductor device, the method comprising:
(a) forming a first electrode having a surface;
(b) depositing an amorphous layer of a first high K dielectric to cover the surface of the first electrode;
(c) depositing a crystalline layer of a second high K dielectric over the amorphous layer; and
(d) annealing the amorphous layer and the crystalline layer together to form a composite dielectric material.

23. The method of claim 22, further comprising forming a second electrode over the composite dielectric material.

24. The method of claim 22, wherein the amorphous layer is less than about 12 nm thick.

25. The method of claim 22, wherein the crystalline layer is less than about 45 nm thick.

26. A method of fabricating a transistor, the method comprising:
(a) forming a source on a semiconductor substrate;
(b) forming a drain on the semiconductor substrate;
(c) depositing an amorphous layer of a first high K dielectric over a surface region of the semiconductor substrate;
(d) depositing a crystalline layer of a second high K dielectric over the amorphous layer;
(e) annealing the amorphous layer and the crystalline layer together to form a composite dielectric material; and
(f) forming a gate material over the composite dielectric material.

27. The method of claim 26, wherein the amorphous layer is less than about 12 nm thick.

28. The method of claim 26, wherein the crystalline layer is less than about 45 nm thick.

29. A high K dielectric material for use in semiconductor devices, the material comprising:
a continuous amorphous layer of a first high K dielectric having a thickness less than about 12 nm; and
a crystalline layer of a second high K dielectric vapor deposited over the continuous amorphous layer, the crystalline layer being less than 45 nm thick.

30. The high K dielectric material of claim 29, wherein at least one of the first and second high K dielectrics is selected from the group consisting of STO, BTO, BST, PZT and SBT.

31. The high K dielectric material of claim 30, wherein the continuous amorphous layer is no greater than 2 nm thick.

32. The high K dielectric material of claim 31, wherein the crystalline layer is ho greater than 30 nm thick.

33. A semiconductor device comprising:
a first electrode formed on a semiconductor substrate;
a second electrode formed on the semiconductor substrate; and
a high K dielectric material disposed between the first electrode and the second electrode, the high K dielectric material being formed from a continuous amorphous layer of a first high K dielectric and a crystalline layer of a second high K dielectric.

34. The semiconductor device of claim 33, wherein the first high K dielectric has a thickness less than 12 nm.

35. The semiconductor device of claim 33, wherein the second high K dielectric has a thickness less than 45 nm.

36. The semiconductor device of claim 33, wherein the first high K dielectric comprises a different material than the second high K dielectric.

37. The semiconductor device of claim 33, wherein the first and second high K dielectrics are annealed such that the high K dielectric material is less than about 30 nm thick and any leakage current is less than about 1×10⁻⁵ A/cm².

38. The semiconductor device of claim 37, wherein the capacitance per unit area of the high K dielectric material is at least 60 fF/μm².

39. A transistor comprising:
a source disposed on a semiconductor substrate;
a drain disposed on the semiconductor substrate; and
a gate region being operable to electrically connect the source and the drain, the gate region including a gate material and a gate dielectric, the gate dielectric comprising a high K dielectric material formed from a continuous amorphous layer of a first high K dielectric and a crystalline layer of a second high K dielectric.

40. The transistor of claim 39, wherein the first high K dielectric has a thickness less than 12 nm.

41. The transistor of claim 39, wherein the second high K dielectric has a thickness less than 45 nm.

42. The transistor of claim 39, wherein the first high K dielectric comprises a different material than the second high K dielectric.

43. The transistor of claim 39, wherein the first and second high K dielectrics are annealed such that the high K dielectric material is less than about 30 nm thick and any leakage current is less than about 1×10 ⁻⁵ A/cm².
